(19) United States
(12) Patent Application Publication
(10) Pub. No.: US 2025/0357308 A1
(43) Pub. Date: Nov. 20, 2025

(54) DEEP TRENCH CAPACITOR (DTC) PAD ON SOLDER RESIST (SR) LAYER

(71) Applicant: QUALCOMM Incorporated, San Diego, CA (US)

(72) Inventors: Joan Rey Villarba BUOT, Escondido, CA (US); Zhijie WANG, San Diego, CA (US); Aniket PATIL, San Diego, CA (US); Hyun-Il MOON, Suwon-si (KR)

(21) Appl. No.: 18/668,749

(22) Filed: May 20, 2024

(51) Int. Cl. H01L 23/522; H01L 23/00; H01L 23/498; H01L 25/065

(52) U.S. Cl. CPC H01L 23/5223; H01L 23/49816; H01L 23/49838; H01L 24/08; H01L 24/32; H01L 25/0652; H01L 2224/08137; H01L 2224/08155; H01L 2224/32145; H01L 2224/32225; H01L 2924/01029; H01L 2924/1431; H01L 2924/1434; H01L 2924/15311; H01L 2924/19041

(57) ABSTRACT

In some aspects, an integrated circuit (IC) includes a substrate, a plurality of pads including at least two deep trench capacitor (DTC) pads disposed on the substrate, a plurality of first metal layer contacts disposed on the DTC pads, a first solder resist (SR) layer disposed on the substrate, the pads and the first metal layer contacts, a plurality of second metal layer contacts disposed on the first metal layer contacts, a second SR layer disposed on the first SR layer and the second metal layer contacts, and a DTC coupled to the second metal layer contacts.

### TECHNICAL FIELD

The present disclosure generally relates to an integrated circuit (IC) package, and more particularly, to an IC package that includes a deep trench capacitor (DTC).

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips, which is different from the semiconductor substrate for forming an IC chip.

Various packaging technologies can be found in many electronic devices, including processors, servers, mobile devices, radio frequency (RF) ICs, etc. Advanced packaging and processing techniques allow for complex devices, such as multi-die devices and system-on-a-chip (SOC) devices, which may include multiple function blocks, with each function block designed to perform a specific function, such as, for example, a microprocessor function, a graphics processing unit (GPU) function, a communication function (e.g., cellular, Wi-Fi, Bluetooth, and/or other communications), or the like.

In mobile devices, such as phones or smart watches, the sizes of SOC devices may be severely constrained. For example, the surface area of a SOC in a mobile device may be severely limited by the overall size of the mobile device. Meanwhile, some components, such as capacitors in a power delivery network (PDN) in a SOC device, for example, may occupy a relatively large area. There may be increasingly tighter limitations on surface areas that can be dedicated to components such as capacitors in modern SOC devices.

Attempts have been made to alleviate the issue of capacitor placement in modern SOC devices. In some examples, a die-side capacitor (DSC) may be placed side-by-side with one or more active dies (e.g., processor dies). In a SOC device, however, the space available for a DSC may be limited by the size of the active dies and any peripheral connections between the bottom laminate and the top package containing one or more additional dies (e.g., memory dies). In some examples, a land-side capacitor (LSC) may be placed between ball grid array (BGA) balls which are on the opposite side of the substrate from the active dies. One example of LSCs that are implemented in modern high-performance SOC devices is the deep trench capacitor (DTC).

In some examples, while the competition for surface area between the capacitor and the active dies may be avoided by placing a DTC as an LSC on the BGA side of the substrate, it may be desirable to reduce the DTC pitch, that is, the distance between the centers of DTC pads, to improve the performance of the PDN in for high-speed and high-performance SOCs for mobile and computing devices, for example.

Attempts have been made to reduce the DTC pitch for LSCs mounted on the land side, that is, the same side of the substrate as the BGA balls. One approach is to use non-solder mask defined (NSMD) pads for mounting the DTC on the land side to reduce the DTC pitch. A problem with that approach, however, is a significant risk of electrical short due to the close distance between the DTC pad and adjacent traces (i.e., metal traces on the land side of the substrate). Another approach is to use solder mask defined (SMD) pads for mounting the DTC on the land side to avoid the risk of electrical short. A problem with that approach, however, is that while electrical short may be avoided, a significant DTC pitch (i.e., the distance between the centers of DTC pads) need be maintained.

Accordingly, there is a need for improved structures for an IC package and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In some aspects, a device includes a substrate; a plurality of pads including at least two deep trench capacitor (DTC) pads disposed on the substrate; a plurality of first metal layer contacts disposed on the DTC pads; a first solder resist (SR) layer disposed on the substrate, the pads and the first metal layer contacts; a plurality of second metal layer contacts disposed on the first metal layer contacts; a second SR layer disposed on the first SR layer and the second metal layer contacts; and a DTC coupled to the second metal layer contacts.

In some aspects, a method of making a device includes forming a plurality of pads including at least two deep trench capacitor (DTC) pads on a substrate; forming a plurality of first metal layer contacts on the DTC pads; forming a first solder resist (SR) layer on the substrate, the pads and the first metal layer contacts; forming a plurality of second metal layer contacts on the first metal layer contacts; forming a second SR layer on the first SR layer and the second metal layer contacts; and forming a DTC on the second metal layer contacts.

In some aspects, an electronic device includes an integrated circuit (IC) package that comprises: a substrate; a plurality of pads including at least two deep trench capacitor (DTC) pads disposed on the substrate; a plurality of first metal layer contacts disposed on the DTC pads; a first solder resist (SR) layer disposed on the substrate, the pads and the first metal layer contacts; a plurality of second metal layer contacts disposed on the first metal layer contacts; a second SR layer disposed on the first SR layer and the second metal layer contacts; and a DTC coupled to the second metal layer contacts.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross-sectional view of a device according to aspects of the disclosure.

FIG. 2 is a partial cross-sectional view of an apparatus, according to aspects of the disclosure.

FIG. 3 illustrates a method for manufacturing a device, according to aspects of the disclosure.

FIG. 4 illustrates a mobile device that may incorporate one or more IC devices and/or IC packages described herein, according to aspects of the disclosure.

FIG. 5 illustrates various electronic devices that may incorporate one or more IC devices and/or IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to an integrated circuit (IC) device that includes a deep trench capacitor (DTC) mounted as a land-side capacitor (LSC) having two layers of solder resist (SR) to reduce the DTC pitch, that is, the distance between the centers of DTC pads, without increasing the risk of electrical short between the DTC pads and other metal contacts in the IC device. It will be appreciated that the various aspects disclosed herein allow the DTC pitch to be reduced without increasing the risk of electrical short on the land side (i.e., ball grid array (BGA) side) of the substrate, thereby improving the performance of power distribution networks (PDN) in IC devices.

In some aspects, the IC devices may be radio frequency (RF) IC devices, analog IC devices, digital IC devices (e.g., microprocessor devices, graphics processing unit (GPU) devices, artificial intelligence (AI) devices, etc.), mixed-signal IC devices, or system-on-a-chip (SOC) devices, for various types of high-speed and high-performance applications including mobile, AI, graphics, gaming, automotive, or other applications.

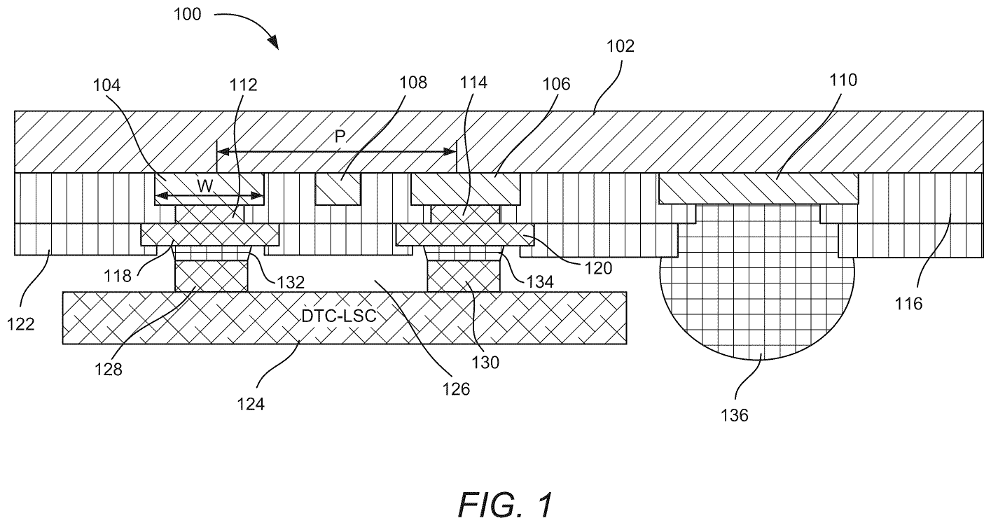

FIG. 1 illustrates a cross-sectional view of a device 100, according to aspects of the disclosure. In some aspects, FIG. 1 is a simplified cross-sectional view of the device 100, and certain details and components of the device 100 may be simplified or omitted in FIG. 1.

In some aspects, the device 100 in FIG. 1 may include a substrate 102. As used herein, the substrate 102 is a packaging substrate for packaging one or more IC chips, which is different from the semiconductor substrate for forming an IC chip. In some aspects, the device 100 includes a plurality of pads 104, 106, 108 and 110 disposed on the substrate 102. In the example illustrated in FIG. 1, two of the pads 104, 106, 108 and 110 are DTC pads 104 and 106, one of the pads 104, 106, 108 and 110 is a ball grid array (BGA) pad 110, and one of the pads 104, 106, 108 and 110 is a trace 108 on the land side of the substrate 102.

In the example illustrated in FIG. 1, the DTC pitch, that is, the distance between the centers of the DTC pads 104 and 106, is denoted as “P,” whereas the width of each of the DTC pads 104 and 106 is denoted as “W.”

In some aspects, the device 100 as shown in FIG. 1 may include a plurality of first metal layer contacts 112 and 114 disposed on the DTC pads 104 and 106, respectively. In some aspects, the device 100 may include a first solder resist (SR) layer 116 disposed on the substrate 102, the pads 104, 106, 108 and 110, and the first metal layer contacts 112 and 114.

In some aspects, the device 100 as shown in FIG. 1 may include a plurality of second metal layer contacts 118 and 120 disposed on the first metal layer contacts 112 and 114, respectively. In some aspects, the device 100 may include a second SR layer 122 disposed on the first SR layer 116 and the second metal layer contacts 118 and 120. In some aspects, the device 100 as shown in FIG. 1 may include a DTC 124 that is electrically coupled to the second metal layer contacts 118 and 120.

In some aspects, by providing a second SR layer 122 in addition to the first SR layer 116 in the device 100 as shown in FIG. 1, both the DTC pitch P and the DTC pad width W may be reduced while preserving electrical insulation between adjacent pads (e.g., between pads 104 and 108 and/or between pads 106 and 108), thus reducing the risk of electrical short between the adjacent pads.

In some aspects, the DTC 124 may comprise a land-side capacitor (LSC). In some aspects, the first metal layer contacts 112 and 114 may comprise copper. In some aspects, the second metal layer contacts 118 and 120 may comprise copper. In some aspects, other types of metals or conductive materials may be used for the first metal layer contacts 112 and 114 or the second metal layer contacts 118 and 120 within the scope of the disclosure.

In some aspects, the DTC 124 may be spaced apart from the second SR layer 122 by a gap 126, as shown in FIG. 1. In some aspects, a plurality of third metal layer contacts 128 and 130 may be provided between the second metal layer contacts 118 and 120, respectively, and the DTC 124, as shown in FIG. 1.

In some aspects, a plurality of solder contacts 132 and 134 may be provided between the third metal layer contacts 128 and 130 and the second metal layer contacts 118 and 120, respectively, as shown in FIG. 1. In some aspects, additional or fewer metal layer contacts and/or additional or fewer solder contacts may be provided between the DTC 124 and the second metal layer contacts 118 and 120 within the scope of the disclosure.

In some aspects, the device 100 may include at least one BGA ball (e.g., BGA ball 136) disposed on at least one of the pads (e.g., BGA pad 110), as depicted in FIG. 1. In some aspects, the device 100 may include one or more additional BGA balls and one or more additional pads than the example illustrated in FIG. 1, within the scope of the disclosure.

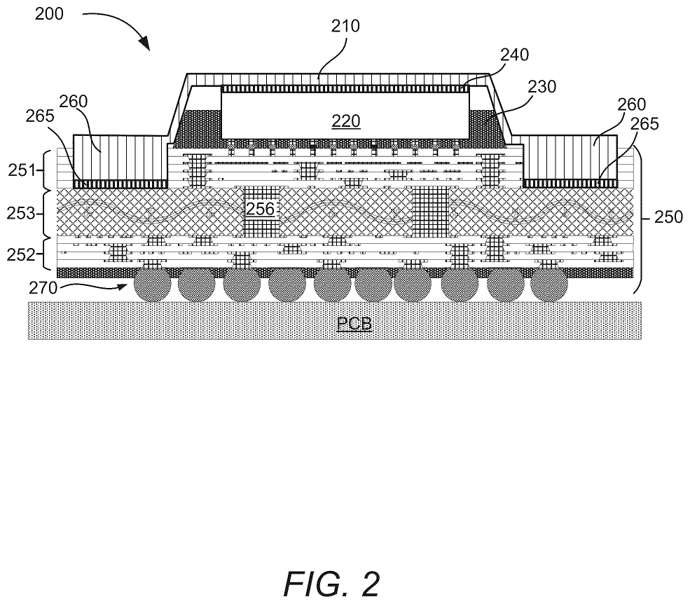

FIG. 2 illustrates a partial cross-sectional view of an apparatus 200, according to aspects of the disclosure. In some aspects, the device 100 having DTC 124 and first and second SR layers 116 and 112 may be implemented on the land side (i.e., the package connector 270 or BGA side) of the package. In some aspects, FIG. 2 is a simplified partial cross-sectional view of the apparatus 200, and certain details and components of the apparatus 200 may be simplified or omitted in FIG. 2. In some aspects, the apparatus 200 may be a portion of an IC package and/or a larger apparatus such as a mobile phone, server, etc.

As shown in FIG. 2, in some aspects, the apparatus 200 includes the device 100 which includes first and second SR layers 116 and 122 to reduce the pitch and the pad width of the DTC 124, thereby maintaining electrical insulation between adjacent pads.

A die 220 is disposed on and electrically coupled to the first metallization structure of the package substrate 250. In some aspects an underfill 230 may optionally be provided. The underfill 230 is disposed between the die 220 and the top surface of the package substrate. In some aspects, the die 220 may be coupled to the lid 210 by an adhesive 240, which may provide mechanical and thermal coupling to the lid 210. In some aspects, a plurality of package connectors 270 are disposed on a bottom surface of the package substrate 250 and electrically coupled to the second metallization structure 252 of the package substrate 250. The package connectors 270 (e.g., solder balls, ball grid array (BGA), solder paste, copper pillars, etc.) are configured to electrically couple the package substrate 250 through the second metallization structure 252 to OEM boards, external components, devices, etc.

In some aspects, the substrate core 253 may include a dielectric material with pre-impregnated reinforcement components embedded therein. In some aspects, the substrate core 253 may include prepreg (also known as PPG), which may include polymer resins with fiber glass sheets impregnated therein. In some aspects, the substrate core 253 includes at least one plated through hole (PTH) 256 disposed through the substrate core 253 configured to couple portions of the first metallization structure 251 and the second metallization structure 252 on opposite sides of the substrate core 253.

In some aspects, the first metallization structure 251 may comprise multiple layers of Ajinomoto build-up film (ABF) or similar other epoxy or resin based layers. In some aspects, the second metallization structure may comprise fiberglass impregnated with resin (prepreg), Ajinomoto build-up film (ABF), a resin coated copper (RCC) build-up film or any similar material. In some aspects, the metal layers and vias of the first metallization structure 251, the second metallization structure 252, PTH 256, and other conductive elements disclosed herein may comprise any high conductive material, such as, copper (Cu), aluminum (AL), silver (Ag), gold (Au) titanium (Ti), nickel (Ni), tin (Sn), lead (Pb), alloys or combinations thereof.

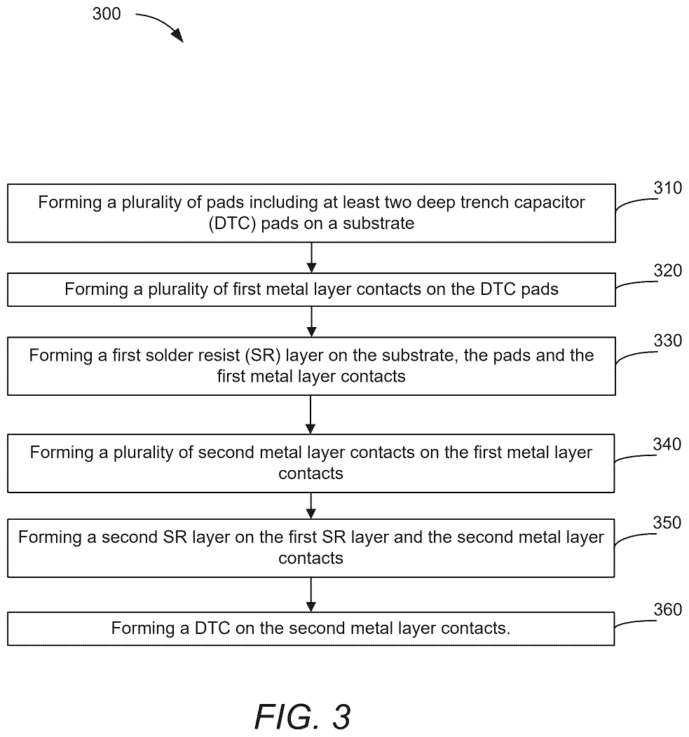

FIG. 3 illustrates a method 300 of manufacturing a device (for example, device 100 as shown in FIG. 1), according to aspects of the disclosure. In some aspects, the device 100 may be an RF IC device, a digital IC device, an analog IC device, a mixed-signal IC device, a SOC device, or the like.

At operation 310, a plurality of pads (e.g., pads 104, 106, 108 and 110) including at least two deep trench capacitor (DTC) pads (e.g., 104 and 106) may be formed on a substrate (e.g., substrate 102).

At operation 320, a plurality of first metal layer contacts (e.g., first metal layer contacts 112 and 114) may be formed on the DTC pads (e.g., DTC pads 104 and 106).

At operation 330, a first solder resist (SR) layer (e.g., first SR layer 116) may be formed on the substrate (e.g., substrate 102), the pads (e.g., pads 104, 106, 108 and 110), and the first metal layer contacts (e.g., first metal layer contacts 112 and 114).

At operation 340, a plurality of second metal layer contacts (e.g., second metal layer contacts 118 and 120) may be formed on the first metal layer contacts (e.g., first metal layer contacts 112 and 114).

At operation 350, a second SR layer (e.g., second SR layer 122) may be formed on the first SR layer (e.g., first SR layer 116) and the second metal layer contacts (e.g., second metal layer contacts 118 and 120).

At operation 360, a DTC (e.g., DTC 124) may be formed on the second metal layer contacts (e.g., second metal layer contacts 118 and 120).

In some aspects, the method 300 may further include additional implementations, such as any single implementation or any combination of implementations described below and/or in connection with one or more other processes described elsewhere herein.

In some aspects, the DTC (e.g., DTC 124) may comprise a land-side capacitor (LSC). In some aspects, the first metal layer contacts (e.g., first metal layer contacts 112 and 114) may comprise copper. In some aspects, the second metal layer contacts (e.g., second metal layer contacts 118 and 120) may comprise copper. In some aspects, other metals or conductive materials may be used for the first metal layer contacts (e.g., first metal layer contacts 112 and 114) and/or the second metal layer contacts (e.g., second metal layer contacts 118 and 120) within the scope of the disclosure.

In some aspects, the DTC (e.g., DTC 124) may be spaced apart from the second SR layer (e.g., second SR layer 122) by a gap (e.g., gap 126). In some aspects, a plurality of third metal layer contacts (e.g., third metal layer contacts 128 and 130) may be formed between the second metal layer contacts (e.g., second metal layer contacts 118 and 120) and the DTC (e.g., DTC 124).

In some aspects, a plurality of solder contacts (e.g., solder contacts 132 and 134) may be formed between the third metal layer contacts (e.g., third metal layer contacts 128 and 130) and the second metal layer contacts (e.g., second metal layer contacts 118 and 120), respectively. In some aspects, additional or fewer metal layer contacts and/or additional or fewer solder contacts may be provided between the DTC (e.g., DTC 124) and the second metal layer contacts (e.g., second metal layer contacts 118 and 120) within the scope of the disclosure.

In some aspects, at least one ball grid array (BGA) ball (e.g., BGA ball 136) may be formed on at least one of the pads (e.g., BGA pad 110). In some aspects, the device 100 may include one or more additional BGA balls and one or more additional pads within the scope of the disclosure.

Although FIG. 3 shows example operations of a method 300, in some implementations, the method 300 may include additional operations, fewer operations, different operations, or differently arranged operations from those depicted in FIG. 3. Additionally, or alternatively, two or more of the operations of the method 300 may be performed in parallel, or may be performed in a temporal sequence different from the order listed or described.

A technical advantage of various aspects of the disclosure is that, with at least two layers of solder resist (SR) in an device for electrical insulation between adjacent pads, the DTC pitch as well as the DTC pad width may be reduced without increasing the risk of electrical short between the DTC pads and other metal contacts in the device. It will also be appreciated that, by reducing the DTC pitch for a land-side DTC that is part of a PDN in a high-speed IC device, the performance of the PDN may be improved.

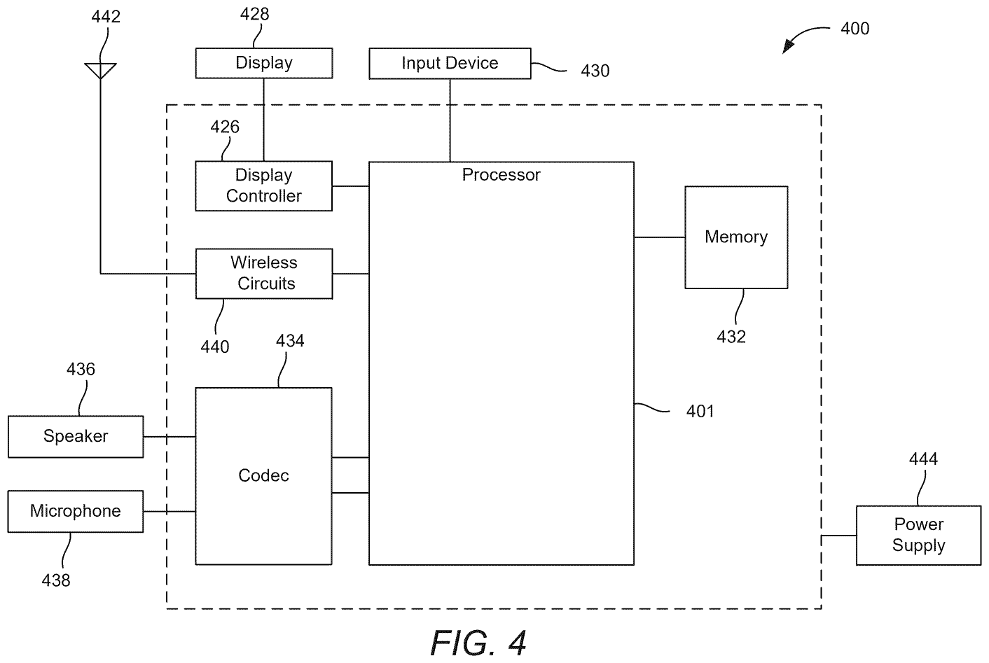

FIG. 4 illustrates a mobile device 400, according to aspects of the disclosure. In some aspects, the mobile device 400 may be implemented by including one or more IC devices including the hybrid substrate with embedded components as disclosed herein.

In some aspects, mobile device 400 may be configured as a wireless communication device. As shown, mobile device 400 includes processor 401. Processor 401 may be communicatively coupled to memory 432 over a link, which may be a die-to-die or chip-to-chip link. Mobile device 400 also includes display 428 and display controller 426, with display controller 426 coupled to processor 401 and to display 428. The mobile device 400 may include input device 430 (e.g., physical, or virtual keyboard), power supply 444 (e.g., battery), speaker 436, microphone 438, and wireless antenna 442. In some aspects, the power supply 444 may directly or indirectly provide the supply voltage for operating some or all of the components of the mobile device 400.

In some aspects, FIG. 4 may include coder/decoder (CODEC) 434 (e.g., an audio and/or voice CODEC) coupled to processor 401; speaker 436 and microphone 438 coupled to CODEC 434; and wireless circuits 440 (which may include a modem, RF circuitry, filters, etc.) coupled to wireless antenna 442 and to processor 401.

In some aspects, one or more of processor 401 (e.g., SoCs, application processor (AP), central processing unit (CPU), digital signal processor (DSP), etc.), display controller 426, memory 432, CODEC 434, and wireless circuits 440 (e.g., baseband interface) including IC devices that are packaged as IC packages and including substrates with an embedded exposed lid according to the various aspects described in this disclosure.

It should be noted that although FIG. 4 depicts a mobile device 400, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

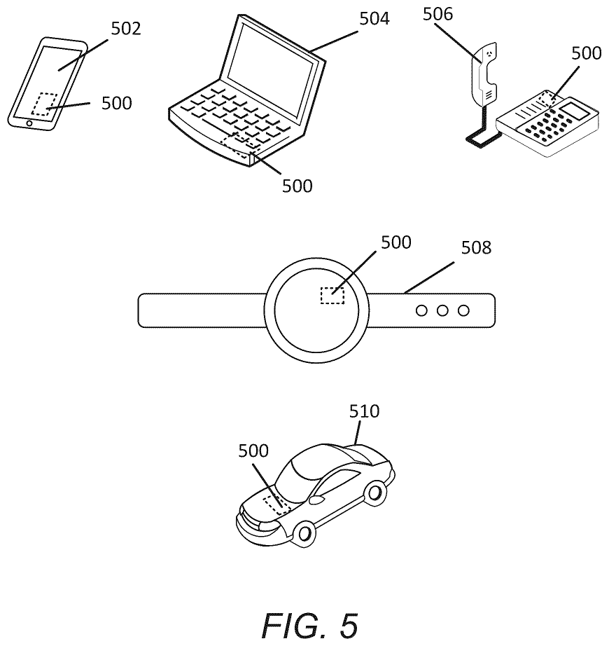

FIG. 5 illustrates various electronic devices that may be integrated with any of the aforementioned devices, semiconductor devices, integrated circuit (IC) packages, integrated circuit (IC) devices, electronic components, interposer packages, package-on-package (POP), System in Package (SiP), or System on Chip (SoC). For example, a mobile phone device 502, a laptop computer device 504, a fixed location terminal device 506, a wearable device 508, or automotive vehicle 510 may include a semiconductor device 500 (e.g., including embedded exposed lids) as described herein. The devices 502, 504, 506 and 508 and the vehicle 510 illustrated in FIG. 5 are merely exemplary. Other apparatuses or devices may also feature the semiconductor device 500 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The devices illustrated in FIG. 5 are merely non-limiting examples. Other electronic devices may also feature the semiconductor devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-5 may be rearranged and/or combined into a single component, process, feature, or function or incorporated in several components, processes, or functions. Additional elements, components, processes, and/or functions may also be added without departing from the disclosure. In some implementations, FIGS. 1-5 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. A device, comprising: a substrate; a plurality of pads including at least two deep trench capacitor (DTC) pads disposed on the substrate; a plurality of first metal layer contacts disposed on the DTC pads; a first solder resist (SR) layer disposed on the substrate, the pads and the first metal layer contacts; a plurality of second metal layer contacts disposed on the first metal layer contacts; a second SR layer disposed on the first SR layer and the second metal layer contacts; and a DTC coupled to the second metal layer contacts.
Clause 2. The device of clause 1, wherein the DTC comprises a land-side capacitor (LSC).
Clause 3. The device of any of clauses 1 to 2, wherein the first metal layer contacts comprise copper.
Clause 4. The device of any of clauses 1 to 3, wherein the second metal layer contacts comprise copper.
Clause 5. The device of any of clauses 1 to 4, wherein the DTC is spaced apart from the second SR layer.
Clause 6. The device of any of clauses 1 to 5, further comprising a plurality of third metal layer contacts disposed between the second metal layer contacts and the DTC.
Clause 7. The device of clause 6, further comprising a plurality of solder contacts disposed between the third metal layer contacts and the second metal layer contacts.
Clause 8. The device of any of clauses 1 to 7, further comprising at least one ball grid array (BGA) ball disposed on at least one of the pads.
Clause 9. The device of any of clauses 1 to 8, wherein the pads comprise solder mask defined (SMD) pads.
Clause 10. A method of making a device, comprising: forming a plurality of pads including at least two deep trench capacitor (DTC) pads on a substrate; forming a plurality of first metal layer contacts on the DTC pads; forming a first solder resist (SR) layer on the substrate, the pads and the first metal layer contacts; forming a plurality of second metal layer contacts on the first metal layer contacts; forming a second SR layer on the first SR layer and the second metal layer contacts; and forming a DTC on the second metal layer contacts.
Clause 11. The method of clause 10, wherein the DTC comprises a land-side capacitor (LSC).
Clause 12. The method of any of clauses 10 to 11, wherein the DTC is spaced apart from the second SR layer.
Clause 13. The method of any of clauses 10 to 12, further comprising forming a plurality of third metal layer contacts between the second metal layer contacts and the DTC.
Clause 14. The method of clause 13, further comprising forming a plurality of solder contacts between the third metal layer contacts and the second metal layer contacts.
Clause 15. The method of any of clauses 10 to 14, further comprising forming at least one ball grid array (BGA) ball on at least one of the pads.
Clause 16. The method of any of clauses 10 to 15, wherein the pads comprise solder mask defined (SMD) pads.
Clause 17. An electronic device, comprising: an integrated circuit (IC) package that comprises: a substrate; a plurality of pads including at least two deep trench capacitor (DTC) pads disposed on the substrate; a plurality of first metal layer contacts disposed on the DTC pads; a first solder resist (SR) layer disposed on the substrate, the pads and the first metal layer contacts; a plurality of second metal layer contacts disposed on the first metal layer contacts; a second SR layer disposed on the first SR layer and the second metal layer contacts; and a DTC coupled to the second metal layer contacts.
Clause 18. The electronic device of clause 17, wherein the DTC is spaced apart from the second SR layer.
Clause 19. The electronic device of any of clauses 17 to 18, wherein the IC package further comprises at least one ball grid array (BGA) ball disposed on at least one of the pads.
Clause 20. The electronic device of any of clauses 17 to 19, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. A device, comprising:
a substrate;
a plurality of pads including at least two deep trench capacitor (DTC) pads disposed on the substrate;
a plurality of first metal layer contacts disposed on the DTC pads;
a first solder resist (SR) layer disposed on the substrate, the pads and the first metal layer contacts;
a plurality of second metal layer contacts disposed on the first metal layer contacts;
a second SR layer disposed on the first SR layer and the second metal layer contacts; and
a DTC coupled to the second metal layer contacts.

2. The device of claim 1, wherein the DTC comprises a land-side capacitor (LSC).

3. The device of claim 1, wherein the first metal layer contacts comprise copper.

4. The device of claim 1, wherein the second metal layer contacts comprise copper.

5. The device of claim 1, wherein the DTC is spaced apart from the second SR layer.

6. The device of claim 1, further comprising a plurality of third metal layer contacts disposed between the second metal layer contacts and the DTC.

7. The device of claim 6, further comprising a plurality of solder contacts disposed between the third metal layer contacts and the second metal layer contacts.

8. The device of claim 1, further comprising at least one ball grid array (BGA) ball disposed on at least one of the pads.

9. The device of claim 1, wherein the pads comprise solder mask defined (SMD) pads.

10. A method of making a device, comprising:
forming a plurality of pads including at least two deep trench capacitor (DTC) pads on a substrate;
forming a plurality of first metal layer contacts on the DTC pads;
forming a first solder resist (SR) layer on the substrate, the pads and the first metal layer contacts;
forming a plurality of second metal layer contacts on the first metal layer contacts;
forming a second SR layer on the first SR layer and the second metal layer contacts; and
forming a DTC on the second metal layer contacts.

11. The method of claim 10, wherein the DTC comprises a land-side capacitor (LSC).

12. The method of claim 10, wherein the DTC is spaced apart from the second SR layer.

13. The method of claim 10, further comprising forming a plurality of third metal layer contacts between the second metal layer contacts and the DTC.

14. The method of claim 13, further comprising forming a plurality of solder contacts between the third metal layer contacts and the second metal layer contacts.

15. The method of claim 10, further comprising forming at least one ball grid array (BGA) ball on at least one of the pads.

16. The method of claim 10, wherein the pads comprise solder mask defined (SMD) pads.

17. An electronic device, comprising:
an integrated circuit (IC) package that comprises:
a substrate;
a plurality of pads including at least two deep trench capacitor (DTC) pads disposed on the substrate;
a plurality of first metal layer contacts disposed on the DTC pads;
a first solder resist (SR) layer disposed on the substrate, the pads and the first metal layer contacts;
a plurality of second metal layer contacts disposed on the first metal layer contacts;
a second SR layer disposed on the first SR layer and the second metal layer contacts; and
a DTC coupled to the second metal layer contacts.

18. The electronic device of claim 17, wherein the DTC is spaced apart from the second SR layer.

19. The electronic device of claim 17, wherein the IC package further comprises at least one ball grid array (BGA) ball disposed on at least one of the pads.

20. The electronic device of claim 17, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
